(19) United States
(12) Patent Application Publication
(10) Pub. No.: US 2025/0385668 A1
(43) Pub. Date: Dec. 18, 2025

(54) TAG WITH DIGITAL CONTROLLED ACTIVE RECTIFIER

(71) Applicant: Renesas Design Austria GmbH, Graz (AT)

(72) Inventor: Richard Gunther Sbüll, Vienna (AT)

(73) Assignee: Renesas Design Austria GmbH, Graz (AT)

(21) Appl. No.: 18/743,510

(22) Filed: Jun. 14, 2024

(51) Int. Cl. H03K 17/30; G06K 7/00; G06K 19/07; H03K 17/16

(52) U.S. Cl. CPC H03K 17/302; G06K 7/0008; G06K 19/0726; H03K 17/162

(57) ABSTRACT

A receiver is provided. The receiver includes an antenna exposed to a magnetic field with a carrier frequency in the RF frequency area, and a rectifier stage of a receiver IC built to extract an internal supply voltage for processing of data with the receiver IC of the receiver. The antenna is built to receive an antenna signal and connected to a tuning circuit built to provide a first received signal at a first input pin of the rectifier stage and a second received signal at a second input pin of the rectifier stage. The rectifier stage includes a first switch, a switch-on stage, a second switch and a switch-off stage.

### FIELD

The present invention relates to a receiver with an antenna.

### BACKGROUND

Known Radio Frequency IDentification communication systems use integrated circuits in RFID readers or transmitters to communicate with active or passive receivers. In a typical application, a passive receiver (e.g., transponder or tag) stores object identification information of an object to which it is attached and the transmitter (e.g., reader) is used to obtain this object information. The transmitter is powered and generates a magnetic RF-Field emitted by its antenna. When the transmitter and the tag are within close proximity of each other, the transmitter generated RF-Field is induced into the antenna of the tag and used to power the passive tag. The tag also has a transceiver to receive the signal from the reader and to transmit a response back to the transmitter as load modulated receiver data signal.

There are standards like ISO/IEC18000-3 or ISO/IEC 14.443 Type A and B or ISO15.693 or ECMA-340 13.56 MHz Near Field Communication (NFC) or the NFC Forum or company standards like Felica from company Sony that define protocols and types of modulation used to transmit information between the tag and the reader. Some or all of these standards define to use an amplitude modulation to transmit an amplitude modulated data signal with digital data within the RF-Field over the air to the tag. ISO14.443 Type A for instance furthermore defines to use a modified Miller encoding to encode the data signal into an encoded data signal for the transmission.

FIG. 1 discloses a system 1 with a reader 2 and a receiver 3 according to the state of the art in a symbolic way reduced to those stages that are relevant for the invention. Reader 2 comprises a reader IC 4, that processes communication data and that is connected to a tuning circuit 5 and an antenna 6 to emit a magnetic field with a NFC (Near Field Communication) resonance frequency fᵣₑₛ of 13.56 MHz. Receiver 3 is exposed to the magnetic field of the reader 2 and comprises an antenna 7 built to receive and provide an antenna signal AS at two antenna connections to a tuning circuit 8. Tuning circuit 8 is dimensioned to receive the antenna AS in resonance to provide a first received signal RF1 at a first input pin of a receiver IC 9 and a second receiver signal RF2 at a second input pin of the receiver IC 9.

Receiver IC 9 comprises a clock extraction stage 10, built to extract an internal clock signal from the antenna signal AS. Receiver IC 9 furthermore comprises a rectifier stage 11, built to rectify a differential received signal U_{DIF} (U_{DIF}=U_{RF1}−U_{RF2}) provided between the first input pin and the second input pin of the receiver IC 9 and built to provide an internal supply voltage VDHF between an output pin and ground potential VS. Receiver IC 9 furthermore comprises a supply voltage limiter stage 12, built to limit the internal supply voltage VDHF at 5V or 3V, just to give two examples, and comprises other stages like a data processor stage not shown in FIG. 1.

The rectifier stage 11 may typically be realized by a bridge rectifier with four diodes. To increase efficiency, actively controlled rectifiers integrating switches are known from other communication areas, but active rectifiers are not commonly used in the NFC area, as the problems described below represent a significant implementation barrier.

FIG. 2 discloses an active rectifier stage 13 in a PMOS implementation and FIG. 3 discloses an active rectifier stage 14 in a NMOS implementation according to the state of the art. The functionality of the active rectifier stage 13 and the active rectifier stage 14 is explained in in the boxes below the circuit drawings of the FIGS. 2 and 3 and known to a person skilled in the art. In principle high side MOS- or Schottky-diodes of a bridge rectifier are replaced by actively controlled first switch MP1 and second switch MP2. If the first received signal RF1 or the second received signal RF2 become larger than the internal supply voltage VDHF, first switch MP1 or second switch MP2 is switched into its connecting status and vice versa. Therefore, the basic functionality of a diode is replaced by a switch, which has a much lower on-voltage drop than the forward voltage of a diode.

For the sake of completeness, it should be mentioned that PMOS and NMOS implementations are equivalent and only differ in whether the high-side or low-side part of a bridge rectifier is actively controlled. For NFC applications, the PMOS implementation is used, because the cross-coupled high side PMOS switches of the NMOS implementation would cause a short circuit of the antenna 7 and the internal supply voltage VDHF during a Miller pause where both the first received signal RF1 and the second received signal RF2 are zero. Therefore, the PMOS implementation is used for all further explanations. However, the concept presented here can be used for PMOS and NMOS implementations in all kind of different application areas.

Below paragraphs describe common problems 1 to 6 with active rectifiers and the corresponding solutions used in state of the art circuits.

1) Body-diode current in the first switch MP1 and second switch MP2: As soon as the first received signal RF1 or the second received signal RF2 is bigger than the internal supply voltage VDHF, the first switch MP1 or the second switch MP2 should be turned on (switched into their connecting status) immediately. Due to the delay in any comparator implementation this is not possible. Therefore, the first switch MP1 and the second switch MP2 are still turned off (switched in their disconnecting status) for a short period of time, even when the first received signal RF1 or the second received signal RF2 are bigger than the internal supply voltage VDHF. This results in current flowing through the body diode of the first switch MP1 or the second switch MP2. Due to bipolar current and possible latch-up any current through the body diode must be avoided.

2) Reverse current in the first switch MP1 and second switch MP2: As soon as the first received signal RF1 or the second received signal RF2 is smaller than the internal supply voltage VDHF, the first switch MP1 or the second switch MP2 should be turned off immediately. Due to the delay in any comparator implementation this is not possible. Therefore, the first switch MP1 and the second switch MP2 are still turned on for a short period of time, even when the first received signal RF1 or the second received signal RF2 are smaller than the internal supply voltage VDHF. This results in a backward current flowing from the output pin with the internal supply voltage VDHF to the first input pin with the first received signal RF1 and the second input pin with the second received signal RF2 of the rectifier, which reduces the overall efficiency of the active rectifiers shown in FIGS. 2 and 3.

In a state of the art circuits 15, as shown in FIG. 4, the body-diode current and the reverse current are suppressed with a delay compensation by introducing leading either a first offset voltage VOS+ or by leading a second offset voltage VOS− via a first offset switch 16 to a first comparator 17, controlling the first switch MP1, and by leading either the first offset voltage VOS+ or by leading the second offset voltage VOS− via a second offset switch 18 to a second comparator 19, controlling the second switch MP2. These offset voltages VOS+ and VOS− with the offset switches 16 and 18 ensure, that the comparison is realized in advance. As a result not only the delay of the comparators 17 and 19, but also the delay of the first switch MP1 and second switch MP2 and the associated drivers can be compensated for with sufficient high offset voltages VOS+ and VOS−.

Ideally, the offset voltages VOS+ and VOS− are selected so that a current through the body diode and a reverse current no longer occur. Since the offset voltages VOS+ and VOS− change depending on process variation, temperature and operating points, a control loop is necessary. In connection with the control loop, the state of the art solution is called delay compensation with control loop, which results in a quite complex circuitry.

3) Multiple Pulsing Problem (MPP): The introduction of above explained leading offset voltages VOS+ and VOS− causes another unwanted effect called Multiple Pulsing Problem. When MPP occurs, the actively controlled first switch MP1 or second switch MP2 switches on and off several times in a half cycle. An oscillation occurs, which is caused by the positive feedback in the delay compensation loop.

MPP can only be avoided respectively circuit stability maintained, if offset voltages VOS+ and VOS− remain in certain limits. Therefore, the dynamic range of the control loop adjusting offset limits VOS+ and VOS− must be limited. To avoid the MPP effect, a compromise regarding delay compensation is necessary, because the maximum values of offset voltage VOS+ and VOS− are limited.

4) Poor efficiency at low output currents of the active rectifier: Since the circuit of the active rectifier and especially the drivers consume additional power compared to a passive rectifier circuit with diodes, the passive implementation with diodes is more efficient at a certain point when the output become smaller.

To solve this problem in state of the art circuits the large first switch MP1 and large second switch MP2 and the associated powerful drivers are usually divided into several smaller switches with weaker drivers. For the maximum output current all groups of switches and associated drivers are activated. The lower the output current, the fewer groups are activated. This reduces self-power consumption in relation to the output current and ultimately increases efficiency with smaller currents.

5) Rectifier Circuit-startup: An active rectifier must be able to start on its own. For this purpose, auxiliary supply circuits are usually implemented that provide the necessary internal voltages for the active rectifier circuit to start-up and provide an output current to supply the receiver IC or NFC chip.

6) NFC communication interference: With an NFC device that comprises the receiver IC, communication also takes place via the magnetic field and power path and the same antenna interface to which the active rectifier is connected. A big problem is that active rectifier circuits and the NFC transceiver usually interfere with and disturb each other. A common approach is to minimize mutual influence through design measures.

Conclusion of above problems of active rectifiers and state of the art solutions: In summary, one can say that the implementation of an active rectifier circuit is very complex and analogue control loops are difficult to control over process variation, temperature and circuit operating points. In addition, in the NFC application area, the RF input voltage of 13.56 MHz is relatively high, which places high demands on the speed of the circuit. For these reasons, active rectifiers are rarely implemented.

### SUMMARY

It is an object of the invention to provide a receiver with an active rectifier that avoids above explained problems of state of the art solutions. This object is achieved by a receiver according to an embodiment of the present disclosure.

This invention presents a novel concept for digitally controlling the switches in active rectifiers which ensures a simple and robust implementation and eliminates the problems of the state of the art solution. In above described state of the art active rectifier circuits, the switch-on time tₒₙ and switch-off time t_{off} of the first switch MP1 and the second switch MP2 is variable and detected by voltage comparators 17 and 19. The delay in the detection and driver circuit is compensated for by an analog control loop as delay compensation.

In contrast to the state of the art active rectifier circuits, with the claimed receiver only the switch-on time tₒₙ of the first switch MP1 and the second switch MP2 is determined with a voltage comparator. The switch-off time t_{off} is not defined by a voltage comparison, but rather by a variable and steered first switch-off time t_{off}, which is given by the equation t_{off}=tₒₙ+tvar. The variable-time tvar is determined by a digital control loop that compares the switch-off time t_{off} with the falling edge of the respective half-wave of the first received signal RF1 at the first input pin. If the switch-off time t_{off} is to the left of the falling edge, the variable-time tvar was too small, and if the switch-off time t_{off} is to the right of the falling edge, the variable time tvar was too large. Since the variable time tvar changes with temperature, process variation and operating point, the control loop needs to estimate the variable time tvar continuously with every half wave.

The optimal switch-off time t_{off} is continuously determined by the previously described control loop of the switch-off stage. Therefore, the reverse current in first switch MP1 and second switch MP2, described as problem 2 above, can be virtually eliminated. Since the switch-off time t_{off} is no longer determined via a voltage comparison, the Multi-Pulsing Problem (MPP), described as problem 3 above, can no longer occur.

Due to the implementation of a digital control loop, the variable-time tvar can only take on quantized values that can be assigned to a unique register value of a counter of the switch-off stage. This eliminates all disadvantages associated with analog control loops like process and temperature dependency.

In a preferred embodiment the body diode current in the first switch MP1 and second switch MP2, described as problem 1 above, is eliminated by bulk control stage for bulk switching with a cross-coupled PMOS structures. Additionally a high-speed single-stage current comparator is used to minimize the switch-on time tₒₙ detection delay.

In a further preferred embodiment and to solve the problem of poor efficiency at low output currents, described as problem 4 above, the first switch MP1 and the second switch MP2 are not used as a pure PMOS switch as in the state of the art implementation, but as a PMOS switch/PMOS diode combination. The gate of the PMOS transistor is either connected to ground potential VS in its switched-on state or with the drain contact in its diode mode. Therefore, it is possible to switch from active mode to pure PMOS diode mode, if active mode is no longer more efficient than diode mode. Active mode is switched on, when e.g., high efficiency and high output current are required.

In addition, the rectifier stage circuit can simply be start-up in diode mode. This eliminates the need to implement complex startup-circuits, described as problem 5 above, that are normally necessary for the start-up of an active rectifier.

NFC communication can also take place in diode mode, which means that it is not affected by the active rectifier and vice versa. Therefore, NFC communication interference, described as problem 6 above, is eliminated.

These and other aspects of the invention will be apparent from and elucidated with reference to the embodiments described hereinafter. The person skilled in the art will understand that various embodiments may be combined.

### BRIEF DESCRIPTION OF THE DRAWINGS

FIG. 1 shows a system with a reader and a receiver with a rectifier stage that share the same magnetic field according to the state of the art.

FIG. 2 shows an active rectifier stage in a PMOS implementation according to the state of the art.

FIG. 3 shows an active rectifier stage in a NMOS implementation according to the state of the art.

FIG. 4 shows an active rectifier stage in a PMOS implementation with offset-voltages to suppress body-diode current and reverse current according to the state of the art.

FIG. 5 shows a receiver with a digital controlled active rectifier according to the invention.

FIGS. 6 and 7 show signals of a computer simulation of significant signal curves during switching in the digital controlled active rectifier according to FIG. 5.

### DETAILED DESCRIPTION OF EMBODIMENTS

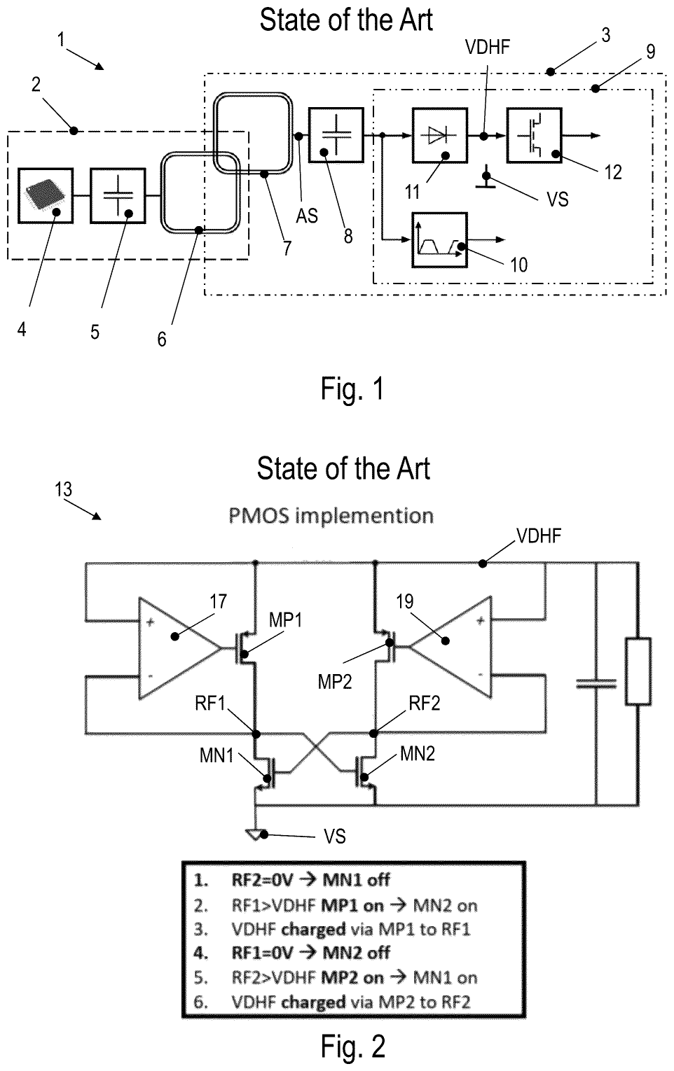

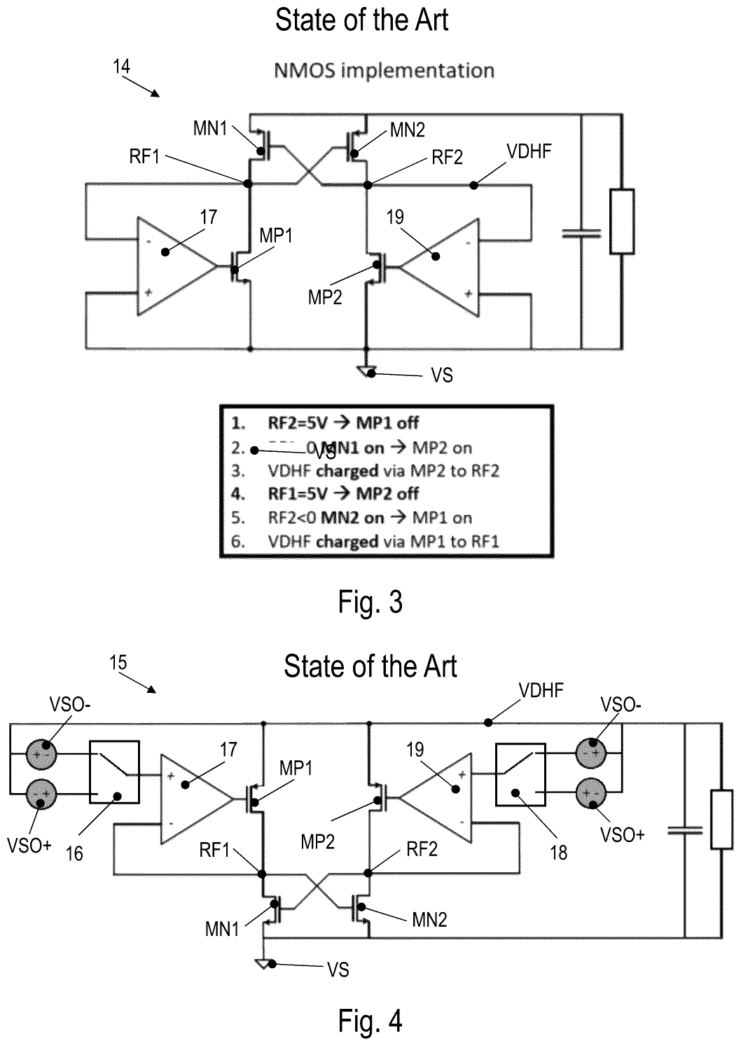

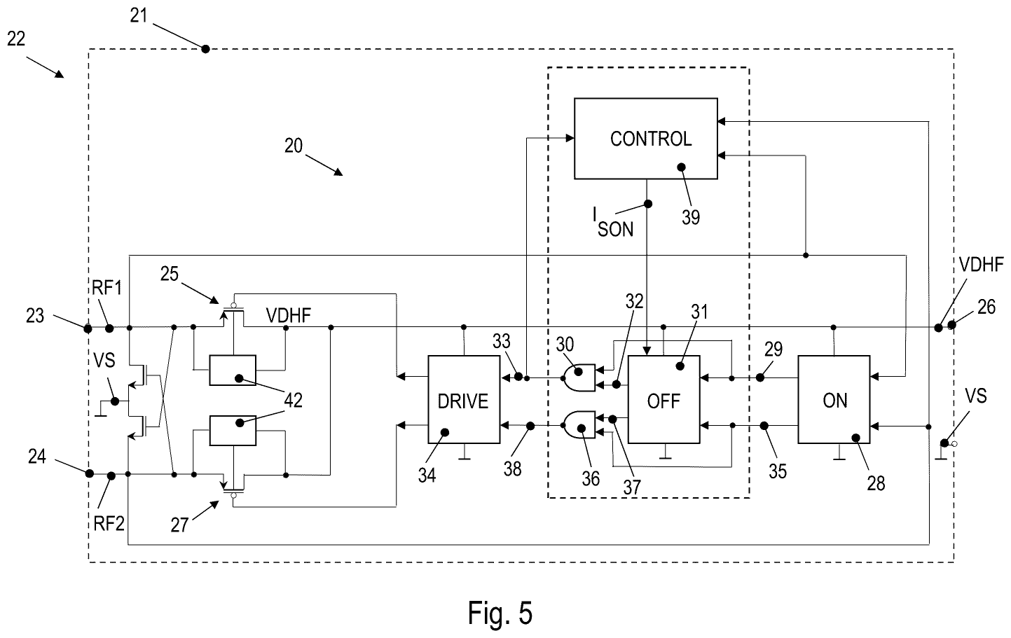

FIG. 5 shows a rectifier stage 20, which is part of a receiver IC 21 of a receiver 22 according to the invention. Receiver 22 comprises an antenna exposed to a magnetic field with a carrier frequency fᵣₑₛ in the RF frequency area and a tuning circuit. Antenna and tuning circuit are not shown in FIG. 5, but are as antenna 7 and tuning circuit 8 as shown in FIG. 1. Rectifier stage 20 is a digitally controlled active rectifier and built to extract an internal supply voltage VDHF for processing of data with the receiver IC 21 of the receiver 22.

The antenna is built to receive an antenna signal AS and connected to the tuning circuit built to provide a first received signal RF1 at a first input pin 23 of the receiver IC 21 and a second received signal RF2 at a second input pin 24 of the receiver IC 21. The rectifier stage 20 comprises a first switch 25 connected between the first input pin 23 and the internal supply voltage VDHF at an output pin 26 of the receiver IC 21. The rectifier stage 20 furthermore comprises a second switch 27 connected between the second input pin 24 and the internal supply voltage VDHF at the output pin 26. The first switch 25 and second switch 27 are built to use the energy of the half-waves of the first received signal RF1 and the second received signal RF2 to generate the internal supply voltage VDHF as in principle known from active rectifiers.

The first switch 25 and the second switch 27 are each realized by a PMOS transistor with their drain contacts as output pins of the first switch 25 and the second switch 27 connected to the output pin 26 with its internal supply voltage VDHF. The source contact of the PMOS transistor of the first switch 25 is connected to the first input pin 23 to receive the first received signal RF1 and the drain contact of the PMOS transistor of the second switch 27 is connected to the second input pin 24 to receive the second received signal RF2.

The rectifier stage 20 furthermore comprises a switch-on stage 28, built to provide a first switch-on signal 29 with an edge at a first switch-on time t_{ON1} to switch the first switch 25 into its connecting status, if the amplitude of the first received signal RF1 at the first input pin 23 exceeds the internal supply voltage VDHF. To achieve that switch-on stage 28 comprises a comparator that compares the first received signal RF1 with the internal supply voltage VDHF and generates the edge in the first switch-on signal 29 at its output, if the amplitude of the first received signal RF1 is greater than the internal supply voltage VDHF.

The first switch-on signal 29 of the switch-on stage 28 is provided to a first NAND gate 30 and provided to a switch-off stage 31. A driver stage 34 is connected to the output of the first NAND gate 30 to receive a first NAND output signal 33 and used to provide an appropriate signal to the gate of the first switch 25 to enable the switching of the first switch 25 into its connecting status or into its disconnecting status. Connecting status is realized when the gate contact of the PMOS transistor is connected to ground potential VS and the disconnecting status or diode mode is realized when the gate contact of the PMOS transistor is connected to the drain contact. The switch-off stage 31 is realized as current controlled time delay module that inverts and delays the first switch-on signal 29 and with this delay adds to the switch-on time t_{ON1} a variable time tvar to generate a first switch-off time t_{off1}. This results in the first switch-off time t_{off1}=t_{ON1}+tvar and the switch-off stage 31 at that first switch-off time t_{off1} generates an edge in the first switch-off signal 32 provided to the first NAND gate 30. In this way the first switch-on signal 29 switches the first switch 25 at the first switch-on time t_{ON1} into its connecting status and the first switch-off signal 32 switches the first switch 25 at the first switch-off time t_{off1} into its disconnecting status.

Analog to above explanation for switching of first switch 25, a second switch-on signal 35 is provided by switch-on stage 28 to a second NAND gate 36 and provided to switch-off stage 31. Switch-off stage 31 generates a second switch-off time t_{off2}=t_{ON2}+tvar and at that second switch-off time t_{off2} generates an edge in a second switch-off signal 37 provided to the second NAND gate 36. The second NAND gate 36 provides a second NAND output signal 38 to driver stage 34 to enable that the second switch-on signal 35 switches the second switch 27 at the second switch-on time t_{ON2} into its connecting status and the second switch-off signal 37 switches the second switch 27 at the second switch-off time t_{off2} into its disconnecting status.

Furthermore, but not shown in FIG. 5, the first NAND output signal 33 and the second NAND output signal 38 are fed back to the switch-on stage 28 to clamp the first switch-on signal 29/the second switch-on signal 35 to high as long as first switch-on signal 29/the second switch-on signal 35 is/are low. This prevents the comparators in the switch-on stage 28 from switching off the first switch 25/the second switch 27 before first switch-off time t_{off1}/the second switch-off time t_{off2} and ultimately before the variable time tvar expires. Therefore, the connecting state is latched as long as variable time tvar has not expired, which means that the disadvantage of the Multiple Pulsing Problem cannot occur. After the variable time tvar has elapsed, the output voltage of the first switch-off signal 32/second switch-off signal 37 becomes high. This also causes the output voltage of the first NAND output signal 33/second NAND output signal 38 become high, the first switch 25/the second switch 27 is/are switched into their disconnecting status and the clamping of the first switch-on signal 29/the second switch-on signal 35 is/are disabled. After that, the same cycle can occur for the second received signal RF2.

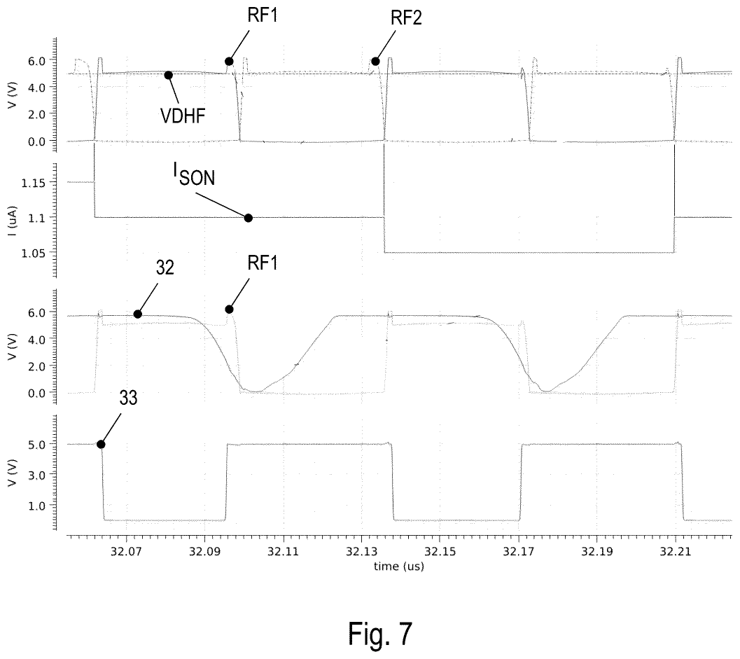

To determine the correct first switch-off time t_{off1} and ultimately avoiding backward current in the first switch 25, the variable time tvar must be continuously regulated. This is done by a digital control stage 39 that compares the falling edge of the first NAND output signal 33 with the falling edge of the first received signal RF1. If the falling edge of the first NAND output signal 33 occurs after the falling edge of the first received signal RF1, the first switch-off time t_{off1} is too late and the variable time tvar is too long. Consequently, the time variable time tvar must be reduced. If the falling edge of the first NAND output signal 33 occurs before the falling edge of the first received signal RF1, the first switch-off time t_{off1} is too early and the variable time tvar is too short. This case is shown in FIG. 7 during time instances 32.09 μs to 32.15 μs. Consequently, the variable time tvar must be increased. The overall goal for the digital control stage 39 is to keep the falling edges of the first received signal RF1 and of the first switch-off time t_{off1} as close together as possible. That is the purpose of the digital control stage 39, which only needs to be implemented for the first received signal RF1, since the determined time tvar can also be used for the second received signal RF2 since the structure of the active rectifier stage 20 is symmetrical. In another embodiment of the invention the digital control stage would only be implemented for the second received signal RF2 or could be implemented for both received signals as well.

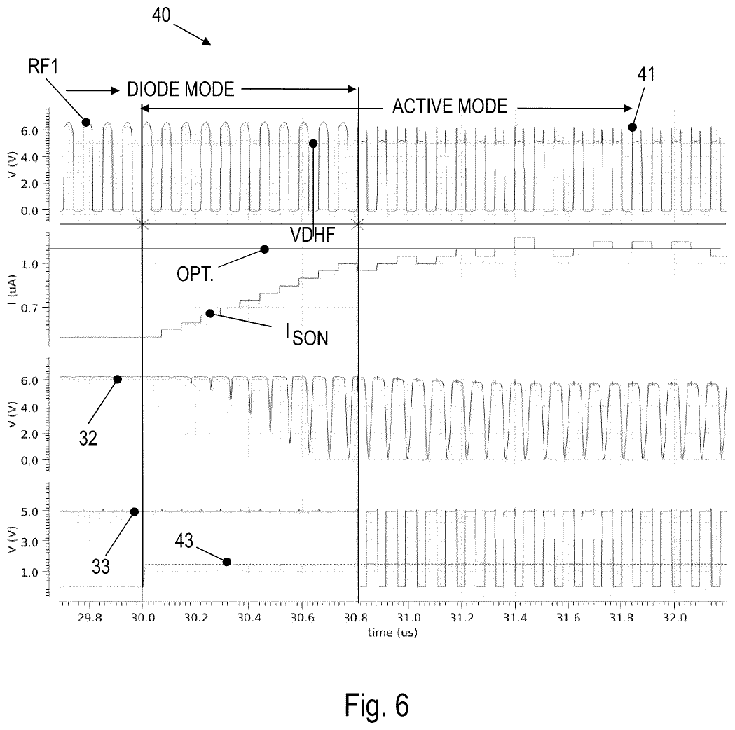

The variable time tvar is proportional to a current I_{SON} of the first switch-on signal 29 supplied to the switch-off stage 31. This current I_{SON} shown in FIG. 6 is generated by the control stage 39 and can take on one of e.g., 32 discrete values in a counter. To ensure that no glitches occur when switching between two current values, the binary number of the counter is converted into a thermometer code. This means that only one transistor in the switch-on stage 28 is switched on or off when the value in the counter increases or decreases by a least significant bit.

The state of the first NAND output signal 33 is evaluated at the falling edge of first received signal RF1. The result of this comparison is initially stored in a latch and routed input of the counter. Depending on the state of the latched first switch-off signal 32, the counter reading is incremented or decremented with each falling edge of the second received signal RF2. This means that the evaluation of whether the variable time tvar was too long or too short takes place with each falling edge of the first received signal RF1 and the processing, i.e., the change in the counter reading with each falling edge of the second received signal RF2. Processing is therefore always delayed by half a period of the first received signal RF1. This small time-delay does not affect the behavior of the control loop. It further ensures that the signal supplied to the counter cannot have an undefined state at any time.

FIGS. 6 and 7 show signals of a computer simulation of significant signal curves during switching on the receiver 22 according to FIG. 5. In this simulation, the reader supplies the receiver 22 with an electromagnetic field. Antenna signal AS is induced on the antenna, which received signals RF1 and RF2 are rectified by the rectifier stage 20. Rectifier stage 20 in turn generates the internal supply voltage VDHF and charges the main output capacitor until an output voltage regulator (shunt) limits the internal supply voltage to a certain value.

Graphs 40 in FIG. 6 show significant signal curves during switching on and operation of the rectifier stage 20. After the reader started to supply the electromagnetic field the circuit of the rectifier stage 20, the first switch 25 and second switch 27 start in a diode mode what is the same as the disconnecting status of the PMOS transistor explained above. In this start-up phase a rather large difference between the peak value of the first received signal RF1/second received signal RF2 and the internal supply voltage VDHF occurs. After about 30 μs active mode is enabled by an active mode enable signal 43 provided by digital control stage 39, but the rectifier stage 20 initially remains in diode mode until the digital control stage 39 has found a close to optimal or optimal first switch-off time t_{off1}/second switch-off time t_{off2} and the corresponding variable time tvar as shown at about 30.8 μs. Only then will the first switch 25 and second switch 27 be switched into their low ohmic connecting status in the active mode as described above. In this active mode FIG. 6 shows that the peak value of the first received signal RF1/second received signal RF2 almost corresponds to the internal supply voltage VDHF. The digital control loop for determining the optimal first switch-off time t_{off1} or the optimal second switch-off time t_{off2} remains active and as shown in FIG. 6, the current I_{SON} of the first switch-on signal 29 oscillates with two last significant bits around the optimal value. It may be stated that a rather large voltage difference between first received signal RF1/the second received signal RF2 and the internal supply voltage VHDF can occur, for instance up to 1.5V. Furthermore, active mode enable signal 43 provided by digital control stage 39 may be switched low to enable NFC transceiver to communicate without disturbances.

Based on graphs 40 shown in FIG. 6 it becomes clear that the digital control loop of control stage 39 continuously tries to find the optimal first switch-off time t_{off1} and oscillates back and forth between a value that is a little too early and a value that is almost optimal. Simulations have shown that these small variations have almost no impact on the overall efficiency of the rectifier stage 20. The “on-spike” 41, which is not necessarily compensated by a leading offset voltage, does not really play a significant role in terms of efficiency, since the maximum current coincides with the peak of the input voltage of the first received signal RF1 and only little current flows at the first switch-on time t_{ON1} and first switch-off time t_{off1}, unless the first switch 25 and the second switch 27 are not switched on too early or are not switched off too late, which causes a relatively large backward current.

To eliminate the current flow through the body diode of the first switch 25 or the second switch 27, the bulk is connected to drain or source using cross-coupled PMOS switches, depending on the voltages present. To achieve that, the first switch 25 and the second switch 27 each comprise a bulk control stage 42 with cross-coupled PMOS switches to connect the bulk of the PMOS transistors either to the source contact or the drain contact.

Further simulation results (not explicitly presented here) show the excellent energy efficiency and robustness of the circuit over process and temperature variations, which is primarily due to the digital control loop and its low sensitivity to these variations.

1. Receiver (22) with an antenna exposed to a magnetic field with a carrier frequency (fᵣₑₛ) in the RF frequency area and with a rectifier stage (20) of a receiver IC built to extract an internal supply voltage for processing of data with the receiver IC (21) of the receiver (22), which receiver (22) comprises:
the antenna built to receive an antenna signal (AS) and connected to a tuning circuit built to provide a first received signal (RF1) at a first input pin (23) of the rectifier stage (20) and a second received signal (RF2) at a second input pin (24) of the rectifier stage (20), which rectifier stage (20) comprises:
a first switch connected between the first input pin and the internal supply voltage at an output pin of the rectifier stage and a switch-on stage (28) built to provide a first switch-on signal (29) to switch the first switch (25) into its connecting status, if the first received signal (RF1) at the first input pin (23) exceeds the internal supply voltage (VDHF), and which rectifier stage (20) comprises
a second switch (27) connected between the second input pin (24) and the internal supply voltage (VDHF) at the output pin (26) and the switch-on stage (28) is built to provide a second switch-on signal (35) to switch the second switch (27) into its connecting status, if the second received signal (RF2) at the second input pin (24) exceeds the internal supply voltage (VDHF),
characterized in, that the rectifier stage (20) comprises a switch-off stage (31) built to provide a first switch-off signal (32) to switch the first switch (25) into its disconnecting status, if a variable and steered first switch-off time (t_{off1}) occurred, and to switch the second switch (27) into its disconnecting status, if a variable and steered second switch-off time (t_{off2}) occurred.

2. Receiver (22) according to claim 1, wherein the switch-off stage (31) comprises a control stage (39) to determine whether the falling edge of the first receiver signal (RF1) or of the first switch-off signal (32) occurs first and/or to determine whether the falling edge of the second receiver signal (RF2) or of the second switch-off signal (37) occurs first and wherein the control stage (39) is built to steer the first switch-off time (t_{off1}) and/or second switch-off time (t_{off2}) to keep these falling edges as close together as possible.

3. Receiver (22) according to claim 2, wherein the control stage (39) is built with each determination to stepwise increase or decrease the first switch-off time (t_{off1}) and/or second switch-off time (t_{off2}).

4. Receiver (22) according to any of the claims 1 to 3, wherein the first switch (25) and the second switch (27) are each realized by a PMOS transistor with their drain contacts as output pins of the first switch (25) and the second switch (27) connected to the internal supply voltage (VDHF) and with the source contact as first input pin (23) of the first switch (25) to receive the first received signal (RF1) and with the source contact as second input pin (24) of the second switch (27) to receive the second received signal (RF2).

5. Receiver (22) according to claim 4, wherein a driver stage (34) is connected to receive the switch-on signal (29, 35) and the switch-off signal (32, 37) and is connected to the gate contacts of the PMOS transistors to operate the first switch (25) as PMOS diode during switching on of the rectifier stage (20) causing a rather large voltage difference between the first received signal (RF1) and the internal supply voltage (VHDF) before switching the first switch (25) into its connecting status and to operate the second switch (27) as PMOS diode during switching on of the rectifier stage (20) causing a rather large voltage difference between the second received signal (RF2) and the internal supply voltage (VHDF) before switching the second switch (27) into its connecting status.

6. Receiver (22) according to any of the claims 4 to 5, wherein the first switch (25) and the second switch (27) each comprise a bulk control stage (42) with cross-coupled PMOS switches to connect the bulk of the PMOS transistors either to the source contact or the drain contact.

7. Receiver (22) according to any of the claims 1 to 6, wherein the antenna and tuning circuit are built to receive the antenna signal (AS) with the carrier frequency of the system defined NFC resonance frequency (fᵣₑₛ) of 13.56 MHz.

1. A receiver comprising:
an antenna exposed to a magnetic field with a carrier frequency in the RF frequency area; and
a rectifier stage of a receiver IC built to extract an internal supply voltage for processing of data with the receiver IC of the receiver;
wherein the antenna is built to receive an antenna signal and connected to a tuning circuit built to provide a first received signal at a first input pin of the rectifier stage and a second received signal at a second input pin of the rectifier stage; and
which rectifier stage comprises:
a first switch connected between the first input pin and the internal supply voltage at an output pin of the rectifier stage;
a switch-on stage built to provide a first switch-on signal to switch the first switch into its connecting status, if the first received signal at the first input pin exceeds the internal supply voltage;
a second switch connected between the second input pin and the internal supply voltage at the output pin and the switch-on stage is built to provide a second switch-on signal to switch the second switch into its connecting status, if the second received signal at the second input pin exceeds the internal supply voltage; and
a switch-off stage built to provide a first switch-off signal to switch the first switch into its disconnecting status, if a variable and steered first switch-off time occurred, and to switch the second switch into its disconnecting status, if a variable and steered second switch-off time occurred.

2. The receiver according to claim 1, wherein the switch-off stage comprises a control stage to determine whether the falling edge of the first receiver signal or of the first switch-off signal occurs first and/or to determine whether the falling edge of the second receiver signal or of the second switch-off signal occurs first and wherein the control stage is built to steer the first switch-off time and/or second switch-off time to keep these falling edges as close together as possible.

3. The receiver according to claim 2, wherein the control stage is built with each determination to stepwise increase or decrease the first switch-off time and/or second switch-off time.

4. The receiver according to claim 1, wherein the first switch and the second switch are each realized by a PMOS transistor with their drain contacts as output pins of the first switch and the second switch connected to the internal supply voltage and with the source contact as first input pin of the first switch to receive the first received signal and with the source contact as second input pin of the second switch to receive the second received signal.

5. The receiver according to claim 4, wherein a driver stage is connected to receive the switch-on signal and the switch-off signal and is connected to the gate contacts of the PMOS transistors to operate the first switch as PMOS diode during switching on of the rectifier stage causing a rather large voltage difference between the first received signal and the internal supply voltage before switching the first switch into its connecting status and to operate the second switch as PMOS diode during switching on of the rectifier stage causing a rather large voltage difference between the second received signal and the internal supply voltage before switching the second switch into its connecting status.

6. The receiver according to claim 4, wherein the first switch and the second switch each comprise a bulk control stage with cross-coupled PMOS switches to connect the bulk of the PMOS transistors either to the source contact or the drain contact.

7. The receiver according to claim 1, wherein the antenna and tuning circuit are built to receive the antenna signal with the carrier frequency of the system defined NFC resonance frequency of 13.56 MHz.
